(19) United States
(12) Patent Application Publication
(10) Pub. No.: US 2022/0310568 A1
(43) Pub. Date: Sep. 29, 2022

(54) DISPLAY BACK PLATE AND METHOD FOR MANUFACTURING SAME, DISPLAY PANEL AND DISPLAY DEVICE

(71) Applicant: BOE Technology Group Co., Ltd., Beijing (CN)

(72) Inventors: Dongni LIU, Beijing (CN); Minghua XUAN, Beijing (CN); Haoliang ZHENG, Beijing (CN); Liang CHEN, Beijing (CN); Li XIAO, Beijing (CN); Seungwoo HAN, Beijing (CN); Hao CHEN, Beijing (CN); Jiao ZHAO, Beijing (CN)

(21) Appl. No.: 17/696,255

(22) Filed: Mar. 16, 2022

(30) Foreign Application Priority Data
Mar. 23, 2021 (CN) 202110309173.1

(51) Int. Cl. H01L 25/075; H01L 27/12; H01L 33/60; H01L 33/62

(52) U.S. Cl. CPC H01L 25/0753; H01L 27/1255; H01L 33/60; H01L 33/62; H01L 2933/0066

(57) ABSTRACT

A drive back plate is provided. The drive back plate includes a base substrate, and a drive circuit and a bonding structure disposed on the base substrate. The drive circuit includes a target drive structure, and a film layer disposed on at least one side of the target drive structure and adjacent to the target drive structure in the drive back plate is an inorganic insulating layer. The bonding structure is disposed on the same layer as the target drive structure, and the material of the bonding structure is the same as the material of the target drive structure.

This application claims priority to Chinese Patent Application No. 202110309173.1, filed on Mar. 23, 2021 and entitled “DISPLAY DEVICE, DISPLAY PANEL, DISPLAY BACK PLATE AND METHOD FOR MANUFACTURING SAME”, the disclosure of which is herein incorporated by reference in its entirety.

### TECHNICAL FIELD

The present disclosure relates to a drive back plate and a method for manufacturing the same, a display panel, and a display device.

### BACKGROUND

Display panels adopting a light-emitting diode (LED) chip as a light-emitting unit may be referred to as LED display panels, and LED display panels have become a research hotspot in the display field.

An LED display panel generally includes a drive back plate, and an LED chip bonded to the drive back plate. For example, the drive back plate includes a bonding pad and the LED chip is bonded to the bonding pad.

### SUMMARY

Embodiments of the present disclosure provide a drive back plate and a method for manufacturing the same, a display panel, and a display device.

In a first aspect, a drive back plate is provided. The drive back plate includes: a base substrate, and a drive circuit and a bonding structure disposed on the base substrate, wherein the drive circuit includes a target drive structure, and a film layer disposed on at least one side of the target drive structure and adjacent to the target drive structure in the drive back plate is an inorganic insulating layer; and the bonding structure and the target drive structure are disposed on a same layer, and a material of the bonding structure is the same as a material of the target drive structure.

In some embodiments, the drive circuit includes at least one of a switch unit and a storage capacitor; and the target drive structure includes any one of a functional structure of the switch unit and a plate of the storage capacitor.

In some embodiments, the drive circuit includes a switch unit, functional structures of the switch unit including a gate, an active layer, a source and a drain; and the target drive structure is the gate of the switch unit.

In some embodiments, the switch unit includes a first gate, a first gate insulating layer, an active layer, a second gate insulating layer, a second gate, an interlayer dielectric layer and a source-drain layer which are sequentially disposed along a direction going away from the base substrate, the source-drain layer including the source and the drain; the target drive structure is the first gate; and the inorganic insulating layer adjacent to the target drive structure includes the first gate insulating layer.

In some embodiments, the drive circuit further includes a storage capacitor, wherein the storage capacitor includes a first plate, and the second gate is reused as a second plate of the storage capacitor.

In some embodiments, the first plate is disposed between the second gate and the source-drain layer; and the interlayer dielectric layer includes: a first interlayer dielectric layer disposed between the second gate and the first plate, and a second interlayer dielectric layer disposed between the first plate and the source-drain layer.

In some embodiments, the drive back plate further includes: a buffer layer disposed between the base substrate and the first gate and between the base substrate and the bonding structure, wherein the inorganic insulating layer adjacent to the target drive structure further includes the buffer layer.

In some embodiments, the drive back plate further includes: a protective layer disposed on a side of the source-drain layer away from the base substrate.

In some embodiments, the drive back plate further includes: an accommodation hole penetrating through the protective layer, the interlayer dielectric layer, the second gate insulating layer and the first gate insulating layer, wherein the bonding structure is disposed in the accommodation hole.

In some embodiments, the drive back plate further includes: an accommodation hole, wherein the bonding structure is disposed in the accommodation hole; and a reflective structure disposed along a sidewall of the accommodation hole, wherein an orthographic projection of the reflective structure on the base substrate surrounds an orthographic projection of the bonding structure on the base substrate.

In some embodiments, the orthographic projection of the reflective structure on the base substrate is of a closed ring shape.

In some embodiments, the reflective structure covers the sidewall of the accommodation hole.

In some embodiments, the drive back plate includes a first gate insulating layer, a second gate insulating layer, a first interlayer dielectric layer, a second interlayer dielectric layer and a protective layer disposed along a direction going away from the base substrate; wherein the accommodation hole penetrates through the second interlayer dielectric layer, the first interlayer dielectric layer, the second gate insulating layer and the first gate insulating layer; the reflective structure is extended from a side of the second interlayer dielectric layer away from the base substrate to the base substrate along the sidewall of the accommodation hole; and the protective layer is extended into the accommodation hole along a surface, away from the sidewall of the accommodating hole, of the reflective structure and covers the reflective structure.

In some embodiments, the drive back plate includes a first gate insulating layer, a second gate insulating layer, a first interlayer dielectric layer, a second interlayer dielectric layer and a protective layer disposed along a direction going away from the base substrate; wherein the accommodation hole penetrates through the protective layer, the second interlayer dielectric layer, the first interlayer dielectric layer, the second gate insulating layer and the first gate insulating layer; and the reflective structure is extended from a side of the protective layer away from the base substrate to the base substrate along the sidewall of the accommodation hole.

In some embodiments, the drive circuit includes a switch unit and a storage capacitor, wherein the switch unit includes a first gate, a first gate insulating layer, an active layer, a second gate insulating layer, a second gate, an interlayer dielectric layer and a source-drain layer which are sequentially disposed along a direction going away from the base substrate, the source-drain layer including a source and a drain; and the storage capacitor includes a first plate disposed between the second gate and the source-drain layer, and the second gate is reused as a second plate of the storage capacitor; the interlayer dielectric layer including a first interlayer dielectric layer disposed between the second gate and the first plate, and a second interlayer dielectric layer disposed between the first plate and the source-drain layer; and the target drive structure is the first gate, and the inorganic insulating layer adjacent to the target drive structure includes the first gate insulating layer; and the drive back plate further includes: a buffer layer, a protective layer and an accommodation hole, wherein the buffer layer is disposed between the base substrate and the first gate, and between the base substrate and the bonding structure, and the inorganic insulating layer adjacent to the target drive structure further includes the buffer layer; the protective layer is disposed on a side of the source-drain layer away from the base substrate; and the accommodation hole penetrates through the protective layer, the second interlayer dielectric layer, the first interlayer dielectric layer, the second gate insulating layer and the first gate insulating layer, and the bonding structure is disposed in the accommodation hole.

In some embodiments, the drive circuit includes a switch unit and a storage capacitor, wherein the switch unit includes a first gate, a first gate insulating layer, an active layer, a second gate insulating layer, a second gate, an interlayer dielectric layer and a source-drain layer which are sequentially disposed along a direction going away from the base substrate, the source-drain layer including a source and a drain; and the storage capacitor includes a first plate disposed between the second gate and the source-drain layer, and the second gate is reused as a second plate of the storage capacitor; the interlayer dielectric layer including a first interlayer dielectric layer disposed between the second gate and the first plate, and a second interlayer dielectric layer disposed between the first plate and the source-drain layer; and the target drive structure is the first gate, and the inorganic insulating layer adjacent to the target drive structure includes the first gate insulating layer; and the drive back plate further includes: a buffer layer, an accommodation hole, a reflective structure and a protective layer, wherein the buffer layer is disposed between the base substrate and the first gate, and between the base substrate and the bonding structure, and the inorganic insulating layer adjacent to the target drive structure further includes the buffer layer; the accommodation hole penetrates through the second interlayer dielectric layer, the first interlayer dielectric layer, the second gate insulating layer and the first gate insulating layer; the reflective structure is extended from a side of the second interlayer dielectric layer away from the base substrate to a side of the buffer layer away from the base substrate along a sidewall of the accommodation hole, an orthographic projection of the reflective structure on the base substrate is of a closed ring shape surrounding an orthographic projection of the bonding structure on the base substrate, and a material of the reflective structure is the same as a material of the source-drain layer; and the protective layer is extended into the accommodation hole along a surface, away from the sidewall of the accommodation hole, of the reflective structure, and covers the reflective structure.

In some embodiments, the drive circuit includes a switch unit and a storage capacitor, wherein the switch unit includes a first gate, a first gate insulating layer, an active layer, a second gate insulating layer, a second gate, an interlayer dielectric layer and a source-drain layer which are sequentially disposed along a direction going away from the base substrate, the source-drain layer including a source and a drain; and the storage capacitor includes a first plate disposed between the second gate and the source-drain layer, and the second gate is reused as a second plate of the storage capacitor; the interlayer dielectric layer including a first interlayer dielectric layer disposed between the second gate and the first plate, and a second interlayer dielectric layer disposed between the first plate and the source-drain layer; and the target drive structure is the first gate, and the inorganic insulating layer adjacent to the target drive structure includes the first gate insulating layer; and the drive back plate further includes: a buffer layer, a protective layer, an accommodation hole and a reflective structure, wherein the buffer layer is disposed between the base substrate and the first gate, and between the base substrate and the bonding structure, and the inorganic insulating layer adjacent to the target drive structure further includes the buffer layer; the protective layer is disposed on a side of the source-drain layer away from the base substrate; the accommodation hole penetrates through the protective layer, the second interlayer dielectric layer, the first interlayer dielectric layer, the second gate insulating layer and the first gate insulating layer; and the reflective structure is extended from a side of the protective layer away from the base substrate to a side of the buffer layer away from the base substrate along a sidewall of the accommodation hole, and an orthographic projection of the reflective structure on the base substrate is of a closed ring shape surrounding an orthographic projection of the bonding structure on the base substrate.

In a second aspect, a method for manufacturing a drive back plate is provided. The method includes: providing a base substrate; and forming a drive circuit and a bonding structure on the base substrate, wherein the drive circuit includes a target drive structure, a film layer disposed on at least one side of the target drive structure and adjacent to the target drive structure in the drive back plate is an inorganic insulating layer, the bonding structure and the target drive structure are disposed on a same layer, and a material of the bonding structure is the same as a material of the target drive structure.

In some embodiments, forming the drive circuit on the base substrate includes: forming at least one of a switch unit and a storage capacitor on the base substrate, wherein the target drive structure includes any one of a functional structure of the switch unit, and a plate of the storage capacitor.

In some embodiments, functional structures of the switch unit include a gate, an active layer, a source and a drain, and the target drive structure is the gate of the switch unit.

In some embodiments, forming the switch unit and the bonding structure on the base substrate includes: forming a first gate and the bonding structure on the base substrate; forming a first gate insulating layer, an active layer, a second gate insulating layer and a second gate sequentially on a side of the first gate away from the base substrate and a side of the bonding structure away from the base substrate; forming an interlayer dielectric layer on a side of the second gate away from the base substrate; and forming a source-drain layer on a side of the interlayer dielectric layer away from the base substrate, the source-drain layer including the source and the drain; wherein the first gate, the first gate insulating layer, the active layer, the second gate insulating layer, the second gate, the interlayer dielectric layer, the source and the drain form the switch unit, the target drive structure is the first gate, and the inorganic insulating layer adjacent to the target drive structure includes the first gate insulating layer.

In some embodiments, forming the drive circuit on the base substrate further includes: forming a storage capacitor on the base substrate, wherein the storage capacitor includes a first plate, and the second gate is reused as a second plate of the storage capacitor.

In some embodiments, forming the interlayer dielectric layer on the side of the second gate away from the base substrate includes: forming a first interlayer dielectric layer on the side of the second gate away from the base substrate; forming the storage capacitor on the base substrate includes: forming the first plate on a side of the first interlayer dielectric layer away from the base substrate; forming the interlayer dielectric layer on the side of the second gate away from the base substrate further includes: forming a second interlayer dielectric on a side of the first plate away from the base substrate; and forming the source-drain layer on the side of the interlayer dielectric layer away from the base substrate includes: forming the source-drain layer on a side of the second interlayer dielectric layer away from the base substrate.

In some embodiments, the method further includes: forming a buffer layer on the base substrate; and forming the first gate and the bonding structure on the base substrate includes: forming the first gate and the bonding structure on a side of the buffer layer away from the base substrate, wherein the inorganic insulating layer adjacent to the target drive structure further includes the buffer layer.

In some embodiments, the method further includes: forming a protective layer on a side of the source-drain layer away from the base substrate.

In some embodiments, the method further includes: forming an accommodation hole, wherein the accommodation hole penetrates through the protective layer, the interlayer dielectric layer, the second gate insulating layer and the first gate insulating layer, and the bonding structure is disposed in the accommodation hole.

In some embodiments, the method further includes: forming an accommodation hole, wherein the bonding structure is disposed in the accommodation hole; forming a reflective structure, wherein the reflective structure is disposed along a sidewall of the accommodation hole, and an orthographic projection of the reflective structure on the base substrate surrounds an orthographic projection of the bonding structure on the base substrate.

In some embodiments, the orthographic projection of the reflective structure on the base substrate is of a closed ring shape.

In some embodiments, the reflective structure covers the sidewall of the accommodation hole.

In some embodiments, forming the drive circuit on the base substrate includes: forming a first gate insulating layer, a second gate insulating layer, a first interlayer dielectric layer and a second interlayer dielectric layer sequentially on the base substrate; wherein the accommodation hole penetrates through the second interlayer dielectric layer, the first interlayer dielectric layer, the second gate insulating layer and the first gate insulating layer; the reflective structure is extended from a side of the second interlayer dielectric layer away from the base substrate to the base substrate along the sidewall of the accommodation hole; and the method further includes: forming a protective layer on a side of the second interlayer dielectric layer away from the base substrate, such that the protective layer is extended into the accommodation hole along a surface, away from the sidewall of the accommodation hole, of the reflective structure and covers the reflective structure.

In some embodiments, forming the drive circuit on the base substrate includes: forming a first gate insulating layer, a second gate insulating layer, a first interlayer dielectric layer and a second interlayer dielectric layer sequentially on the base substrate; and the method further includes: forming a protective layer on a side of the second interlayer dielectric layer away from the base substrate; wherein the accommodation hole penetrates the protective layer, the second interlayer dielectric layer, the first interlayer dielectric layer, the second gate insulating layer and the first gate insulating layer; the reflective structure is extended from a side of the protective layer away from the base substrate to the base substrate along the sidewall of the accommodation hole.

In a third aspect, a display panel is provided. The display panel includes: the drive back plate in the first aspect or any optional embodiment of the first aspect; and a light-emitting device; wherein the light-emitting device is bonded to the bonding structure of the drive back plate.

In some embodiments, the bonding structure includes a first bonding portion and a second bonding portion, and the light-emitting device includes a first electrode and a second electrode, wherein the first electrode is bonded to the first bonding portion, and the second electrode is bonded to the second bonding portion.

In a fourth aspect, a display device is provided. The display device includes the display panel according to the third aspect.

### BRIEF DESCRIPTION OF THE DRAWINGS

FIG. 1 is a schematic structural diagram of a drive back plate according to an embodiment of the present disclosure;

FIG. 2 is a partial front view of a drive back plate according to an embodiment of the present disclosure;

FIG. 3 is a schematic structural diagram of another drive back plate according to an embodiment of the present disclosure;

FIG. 4 is a schematic structural diagram of still another drive back plate according to an embodiment of the present disclosure;

FIG. 5 is a partial front view of another drive back plate according to an embodiment of the present disclosure;

FIG. 6 is a flowchart of a method for manufacturing a drive back plate according to an embodiment of the present disclosure;

FIG. 7 is a flowchart of another method for manufacturing a drive back plate according to an embodiment of the present disclosure;

FIG. 8 is a schematic diagram after a buffer layer is formed on a base substrate according to an embodiment of the present disclosure;

FIG. 9 is a schematic diagram after a first gate and a bonding structure are formed on a side of the buffer layer away from the base substrate according to an embodiment of the present disclosure;

FIG. 10 shows a schematic diagram after a first gate insulating (GI) layer, an active layer, a second GI layer, a second gate, a first interlayer dielectric (ILD) layer, a first plate, a second ILD layer and a source-drain layer are formed on a side of the first gate away from the base substrate and a side of the bonding structure away from the base substrate according to an embodiment of the present disclosure;

FIG. 11 is a schematic diagram after a protective layer is formed on a side of the source-drain layer away from the base substrate according to an embodiment of the present disclosure;

FIG. 12 is a flowchart of still another method for manufacturing a drive back plate according to an embodiment of the present disclosure;

FIG. 13 is a flowchart of yet still another method for manufacturing a drive back plate according to an embodiment of the present disclosure;

FIG. 14 shows a schematic diagram after a first GI layer, an active layer, a second GI layer, a second gate, a first ILD layer, a first plate and a second ILD layer are formed on a side of the first gate away from the base substrate and a side of the bonding structure away from the base substrate according to an embodiment of the present disclosure;

FIG. 15 is a schematic diagram after an accommodation hole is formed according to an embodiment of the present disclosure;

FIG. 16 is a schematic diagram after a source-drain layer and a reflective structure are formed according to an embodiment of the present disclosure;

FIG. 17 is a schematic structural diagram of a display panel according to an embodiment of the present disclosure;

FIG. 18 is a schematic structural diagram of another display panel according to an embodiment of the present disclosure;

FIG. 19 is a schematic structural diagram of still another display panel according to an embodiment of the present disclosure;

FIG. 20 is a partial front view of a display panel according to an embodiment of the present disclosure; and

FIG. 21 is a partial front view of another display panel according to an embodiment of the present disclosure.

### DETAILED DESCRIPTION

Embodiments of the present disclosure are described below with reference to the accompanying drawings. The following embodiments may be implemented in various ways and should not be construed as being limited to the embodiments set forth herein. These embodiments are provided to make the present disclosure complete, and to convey the concept of the present disclosure to those skilled in the art by way of example. The same reference numerals in the accompanying drawings denote the same or similar structures, and thus their detailed descriptions are omitted. Furthermore, the accompanying drawings are merely schematic illustrations of the present disclosure and are not necessarily drawn to scale.

In the present disclosure, the terms “one,” “a/an,” “the,” “said,” and “at least one” and the like are intended to mean the presence of one or more elements/components/and the like. The terms “comprising/including” and “having” and the like are intended to indicate an open-ended inclusion and mean that additional elements/components/and the like may be present in addition to the listed elements/components/and the like. The terms “first,” “second,” “third,” and “fourth,” etc. are used as labels only and are not intended to limit the number of their objects.

LED display panels have the advantages of self-illumination, high brightness, low power consumption, high resolution, high color saturation, high efficiency, long life, small pixel size (e.g., the pixel size can reach micron level) and the like. Moreover, compared with organic light-emitting diode (OLED) display panels that are also self-luminous displays, the luminescent materials of the LED display panels are not easily affected by environment, the luminous performance is relatively stable, and the display image has no afterimages. Therefore, LED display panels have become a research hotspot in the display field.

An LED display panel generally includes a drive back plate and an LED array. The LED array includes a plurality of LED chips. The drive back plate includes a bonding pad and a drive circuit. The bonding pad is electrically connected to the drive circuit. The LED chips are bonded to the bonding pad. The drive circuit is configured to drive the LED chips to emit light. The LED chip can be used as a light-emitting unit of the LED display panel and emit light independently, such that the LED display panel displays images. The LED chip may be micron size. For example, the LED chip is a Micro LED chip with a size of less than 100 μm or a Mini LED chip with a size of 100 μm˜300 μm. Correspondingly, the LED display panel may be a Micro LED display panel or a Mini LED display panel.

During manufacture of the LED display panel, the drive back plate and the LED chips are first manufactured, and then the LED chips are transferred to the drive back plate, and the LED chips are bonded to the bonding pad in the drive back plate to obtain the LED display panel. For example, during manufacture of a full-color Micro LED display panel, the drive back plate, red Micro LED chips (that is, Micro LED chips which emit red light), green Micro LED chips (that is, Micro LED chips which emit green light) and blue Micro LED chips (that is, Micro LED chips which emit blue light) are first manufactured, and then the red Micro LED chips, green Micro LED chips and blue Micro LED chips are transferred to the drive back plate to obtain a Micro LED display panel. The red Micro LED chips, the green Micro LED chips and the blue Micro LED chips may be driven to emit light according to a certain timing sequence, such that the Micro LED display panel displays color images.

In the process of manufacturing the drive back plate, in order to prevent the bonding pad from being oxidized, it is generally necessary to provide at least one additional inorganic insulating layer to separate the bonding pad from an organic film layer with poor water and oxygen barrier properties, so as to prevent the bonding pad from being in contact with the organic film layer. However, in this manner, the number of film layers of the drive back plate is usually increased, which increases the complexity of manufacture of the drive back plate. For example, at least 14 times of patterning processes (mask) are required during manufacture of drive back plate at present.

In addition, the light-emitting angle of the LED chip is relatively large (for example, the light-emitting angle of the LED chip is 360°, that is, the LED chip emits light at a 360° angle), which easily leads to a low light-emitting brightness in the front viewing angle of the LED display panel. Thus, the display effect of the LED display panel is affected, and the light utilization ratio of the LED chip is low.

Embodiments of the present disclosure provide a drive back plate and a method for manufacturing the same, a display panel, and a display device. The drive back plate includes a drive circuit and a bonding structure. The drive circuit includes a target drive structure. In the drive back plate, a film layer on at least one side of the target drive structure and adjacent to the target drive structure (i.e., a film layer in contact with the target drive structure) is an inorganic insulating layer. The bonding structure is disposed on the same layer as the target drive structure, and the material of the bonding structure is the same as the material of the target drive structure. Since the bonding structure and the target drive structure are disposed on the same layer, and the film layer, in contact with the target drive structure, in the drive back plate that is an inorganic insulating layer, in the process of manufacturing the drive back plate, the film layer in contact with the bonding structure is an inorganic insulating layer which can prevent the bonding structure from being oxidized. Since the bonding structure and the target drive structure are disposed on the same layer, and the material of the bonding structure is the same as the material of the target drive structure, the bonding structure and the target drive structure may be manufactured through the one-time patterning process, which helps simplify the manufacturing process of drive back plate.

The technical solutions of the present disclosure are described below in conjunction with the accompanying drawings. The embodiment of the drive back plate is introduced first.

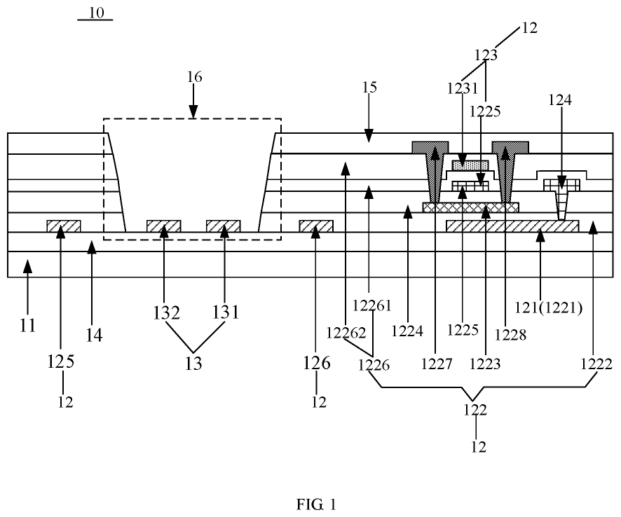

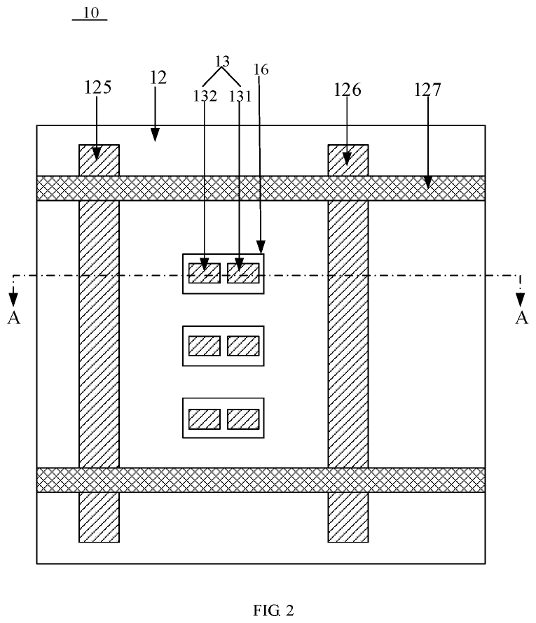

FIG. 1 is a schematic structural diagram of a drive back plate 10 according to an embodiment of the present disclosure. FIG. 2 is a partial front view of a drive back plate 10 according to an embodiment of the present disclosure. For example, FIG. 1 is a sectional view taken along A-A of FIG. 2. The drive back plate 10 includes a base substrate 11, and a drive circuit 12 and a bonding structure 13 disposed on the base substrate 11. The drive circuit 12 includes a target drive structure 121. In the drive back plate 10, a film layer disposed on at least one side of the target drive structure 121 and adjacent to the target drive structure 121 is an inorganic insulating layer. The bonding structure 13 and the target drive structure 121 are disposed on the same layer. The material of the bonding structure 13 is the same as the material of the target drive structure 121. The bonding structure 13 and the target drive structure 121 may be manufactured through the one-time patterning process. Optionally, the material of the bonding structure 13 and the material of the target drive structure 121 are both metal. For example, the material of the bonding structure 13 and the material of the target drive structure 121 are both copper.

The bonding structure 13 is configured to drive the back plate 10 and a light-emitting device (not shown in FIG. 1 and FIG. 2). The drive circuit 12 is configured to drive the light-emitting device to emit light. As shown in FIG. 1, the bonding structure 13 includes a first bonding portion 131 and a second bonding portion 132. Both the first bonding portion 131 and the second bonding portion 132 may be bonding pads. The first bonding portion 131, the second bonding portion 132 and the target drive structure 121 are arranged at intervals. The first bonding portion 131 may be configured to be bonded to a first electrode of the light-emitting device. The second bonding portion 132 may be configured to be bonded to a second electrode of the light-emitting device. One of the first electrode and the second electrode is an anode and the other one is a cathode. For example, the first electrode is an anode and the second electrode is a cathode.

In summary, in the drive back plate according to the embodiment of the present disclosure, the bonding structure and the target drive structure are disposed on the same layer, and the film layer in contact with the target drive structure is an inorganic insulating layer. Therefore, during the manufacture of the drive back plate, the film layer in contact with the bonding structure is an inorganic insulating layer and the inorganic insulating layer can prevent the bonding structure from being oxidized. Since the bonding structure and the target drive structure may be manufactured through the one-time patterning process, the manufacturing process of the drive back plate is simplified and the production cost of the drive back plate is reduced.

In the embodiment of the present disclosure, the base substrate 11 is a rigid substrate or a flexible substrate. For example, the base substrate 11 is a rigid substrate made of a material with certain rigidness, such as glass, quartz, or transparent resin. Alternatively, the base substrate 11 is a flexible substrate made of a flexible material such as polyimide (PI).

In the embodiment of the present disclosure, the drive circuit 12 may include at least one of a switch unit and a storage capacitor. The target drive structure 121 includes a functional structure of the switch unit or a plate of the storage capacitor. For example, the functional structures of the switch unit include a gate, an active layer, a source and a drain, and the target drive structure 121 is the gate of the switch unit. The switch unit may be a thin-film transistor (TFT). For example, the switch unit is a bottom-gate TFT, a top-gate TFT or a double-gate TFT. The embodiments of the present disclosure are described by taking an example in which the drive circuit 12 includes a switch unit 122 and a storage capacitor 123, the switch unit 122 is a double-gate TFT, and the target drive structure 121 is the gate of the switch unit 122.

As shown in FIG. 1, the switch unit 122 includes a first gate 1221, a first GI layer 1222, an active layer 1223, a second GI layer 1224, a second gate 1225, an ILD layer 1226 and a source-drain layer which are sequentially disposed in the direction going away from the base substrate 11. The source-drain layer includes a source 1227 and a drain 1228. The source 1227 and the drain 1228 are electrically connected to the active layer 1223. The drain 1228 is electrically connected to the first bonding portion 131 (not shown in FIG. 1). The first GI layer 1222 covers the first gate 1221. The second GI layer 1224 covers the active layer 1223 and the first GI layer 1222. The ILD layer 1226 covers the second gate 1225 and the second GI layer 1224. The ILD layer 1226 and the second GI layer 1224 each have a source via and a drain via. The source 1227 is electrically connected to the active layer 1223 through the source via, and the drain 1228 is electrically connected to the active layer 1223 through the drain via hole. The second gate 1225 and the first gate 1221 are electrically connected to form a double gate of the switch unit 122. For example, the drive circuit 12 further includes a connection structure 124. The connection structure 124 and the second gate 1225 are disposed on the same layer. The second GI layer 1224 and the first GI layer 1222 are provided with connection holes. The connection structure 124 and the second gate 1225 are electrically connected (not shown in FIG. 1). The connection structure 124 is electrically connected to the first gate 1221 through the connection hole, such that the second gate 1225 and the first gate 1221 are electrically connected through the connection structure 124.

In the embodiment of the present disclosure, the orthographic projection of the second gate 1225 on the base substrate 11, the orthographic projection of the active layer 1223 on the base substrate 11 and the orthographic projection of the first gate 1221 on the base substrate 11 have an overlapped region. For example, the orthographic projection of the active layer 1223 on the base substrate 11 is partially overlapped with the orthographic projection of the first gate 1221 on the base substrate 11, and the orthographic projection of the active layer 1223 on the base substrate 11 covers the orthographic projection of the second gate 1225 on the base substrate 11.

In the embodiment of the present disclosure, the material of the first gate 1221 may be metal, such as copper. The material of the first GI layer 1222 may be an inorganic insulating material, such as silicon oxide and silicon nitride. The material of the active layer 1223 may be polysilicon, amorphous silicon or metal oxide. The material of the second GI layer 1224 may be an inorganic insulating material such as silicon oxide and silicon nitride. The material of the second gate 1225 may be metal, such as copper. The material of the ILD layer 1226 may be an inorganic insulating material such as silicon oxide and silicon nitride. The source-drain layer may have a single-layered structure or a multi-layered structure. For example, the source-drain layer includes a first metal layer, a second metal layer and a third metal layer which are laminated sequentially along the direction going away from the base substrate 11. The material of the first metal layer is the same as the material of the third metal layer. The material of the second metal layer is different from the material of the first metal layer and the material of the third metal layer. For example, the material of the first metal layer and the material of the third metal layer are titanium, and the material of the second metal layer is aluminum.

In an optional embodiment, the target drive structure 121 is the first gate 1221 of the switch unit 122. The inorganic insulating layer, adjacent to the target drive structure 121, in the drive back plate 10 (i.e., the inorganic insulating layer adjacent to the first gate 1221) includes the first GI layer 1222. That is, the inorganic insulating layer in contact with the target drive structure 121 includes the first GI layer 1222. Since the bonding structure 13 and the target drive structure 121 are disposed on the same layer and the film layer, in contact with the target drive structure 121, in the drive back plate 10 includes the first GI layer 1222, the first GI layer 1222 can prevent the bonding structure 13 from being oxidized. In the embodiment of the present disclosure, the first GI layer 1222 serves as the film layer in contact with the target drive structure 121, and there is no need to provide an additional inorganic insulating layer to isolate the bonding structure 13 from the organic film layer, which can simplify the manufacturing process of the drive back plate.

As shown in FIG. 1, the storage capacitor 123 includes a first plate 1231. An orthographic projection of the second gate 1225 on the base substrate 11 is overlapped with an orthographic projection of the first plate 1231 on the base substrate 11. The second gate 1225 is reused as a second plate of the storage capacitor 123. That is, the second gate 1225 serves as the gate of the switch unit 122 to control the switch-on/switch-off of the switch unit 122 on the one hand, and forms the storage capacitor 123 together with the first plate 1231 on the other hand.

In an optional embodiment, the first plate 1231 is disposed between the second gate 1225 and the source-drain layer. The ILD layer 1226 includes a first ILD layer 12261 and a second ILD layer 12262. The first ILD layer 12261 is disposed between the second gate 1225 and the first plate 1231. The first ILD layer 12261 covers the second gate 1225 and the second GI layer 1224, and the first ILD layer 12261 may isolate the second gate 1225 from the first plate 1231, such that the second gate 1225 is insulated from the first plate 1231. The second ILD layer 12262 is disposed between the first plate 1231 and the source-drain layer. The second ILD layer 12262 covers the first plate 1231 and the first ILD layer 12261, and the second ILD layer 12262 may isolate the first plate 1231 from the source-drain layer, such that the first plate 1231 is insulated from conductive structures (e.g., the source 1227 and the drain 1228) in the source-drain layer.

In an optional embodiment, the drive back plate 10 further includes a buffer layer 14. The material of the buffer layer 14 may be an inorganic insulating material such as silicon oxide and silicon nitride. The buffer layer 14 is disposed between the base substrate 11 and the first gate 1221 and between the base substrate 11 and the bonding structure 13. For example, the first gate 1221 and the bonding structure 13 are both disposed on the side of the buffer layer 14 away from the base substrate 11. The inorganic insulating layer, adjacent to the target drive structure 121, in the drive back plate 10 (i.e., the inorganic insulating layer adjacent to the first gate 1221) further includes the buffer layer 14. That is, the inorganic insulating layer, in contact with the target drive structure 121, in the drive back plate 10 further includes the buffer layer 14. Thus, the inorganic insulating layer in contact with the bonding structure 13 includes the buffer layer 14. The buffer layer 14 can prevent the bonding structure 13 from being oxidized. In the embodiment of the present disclosure, the buffer layer 14 is used as the film layer in contact with the bonding structure 13, and there is no need to provide an additional inorganic insulating layer to isolate the bonding structure 13 from the organic film layer, which can simplify the manufacturing process of the drive back plate.

In an optional embodiment, the drive back plate 10 further includes a protective layer 15. The protective layer 15 is disposed on the side of the source-drain layer away from the base substrate 11. The protective layer 15 may cover the source-drain layer and the ILD layer 1226. The protective layer 15 may protect conductive structures (e.g., the source 1227 and the drain 1228) in the source-drain layer. The protective layer 15 may be a single-layered structure or a multi-layered structure. For example, the protective layer 15 includes a passivation (PVX) layer and a planarization (PLN) layer laminated in a direction going away from the base substrate 11. The PVX layer may be made of an inorganic insulating material such as silicon oxide and silicon nitride, or an organic resin material, and the PLN layer may be made of an organic resin material, which is not limited in the embodiments of the present disclosure.

In an optional embodiment, the drive back plate 10 further includes an accommodation hole 16. The accommodation hole 16 is configured to accommodate the light-emitting device. The bonding structure 13 is disposed in the accommodation hole 16 so as to facilitate the bonding of the bonding structure 13 and the light-emitting device. The structure of the accommodation hole 16 may be matched with the structure of the light-emitting device. The bottom surface of the accommodation hole 16 may be the side of the buffer layer 14 away from the base substrate 11. The bonding structure 13 may be disposed on the bottom surface of the accommodation hole 16.

In an optional embodiment, the structure of the accommodation hole 16 is of a trumpet shape. The angle between the sidewall of the accommodation hole 16 and the base substrate 11 may be 60°-70°. For example, a longitudinal section of the accommodation hole 16 is of an inverted trapezoid shape, which may be an isosceles trapezoid. The longitudinal section of the accommodation hole 16 may be perpendicular to the board surface of the base substrate 11. The angle between the sidewall of the accommodation hole 16 and the base substrate 11 may be equal to the angle between the upper base of the inverted trapezoid and the waist of the inverted trapezoid. The cross section of the accommodation hole 16 may be of a rectangle shape, and the cross section of the accommodation hole 16 is parallel to the board surface of the base substrate 11.

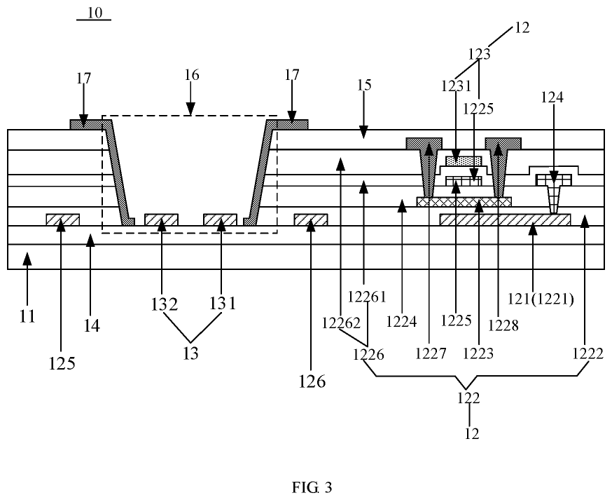

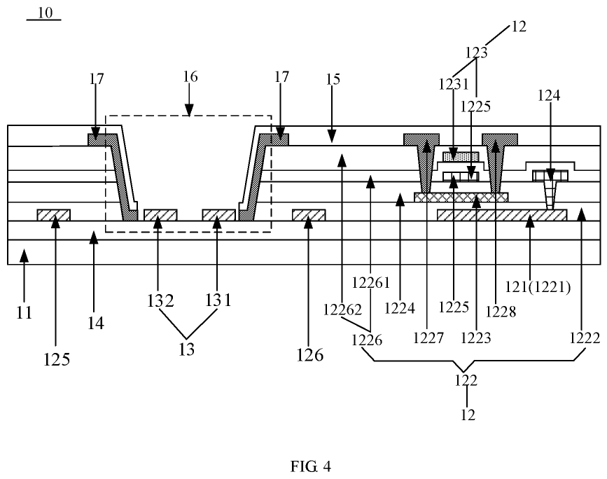

FIG. 3 and FIG. 4 are schematic structural diagrams of other two drive back plates 10 according to embodiments of the present disclosure. As shown in FIGS. 1 and 3, the accommodation hole 16 penetrates through the protective layer 15, the ILD layer 1226 (including the first ILD layer 12261 and the second ILD layer 12262), the second GI layer 1224 and the first GI layer 1222. As shown in FIG. 4, the accommodation hole 16 penetrates through the ILD layer 1226 (including the first ILD layer 12261 and the second ILD layer 12262), the second GI layer 1224 and the first GI layer 1222. The descriptions of the structure of the accommodation hole 16 and the film layers through which the accommodation hole 16 penetrates in the embodiments of the present disclosure are merely exemplary. The structure of the accommodation hole 16 and the film layers through which the accommodation hole 16 penetrates may be designed according to the requirements of the drive back plate. For example, the cross section of the accommodation hole 16 may also be of a circle shape, a pentagon shape, a hexagon shape or other regular or irregular shapes. The structure of the accommodation hole 16 and the film layers through which the accommodation hole 16 penetrates are not limited in the embodiments of the present disclosure.

FIG. 5 is a partial front view of another drive back plate 10 according to an embodiment of the present disclosure. FIG. 3 or FIG. 4 may be a sectional view of portion B-B of FIG. 5. As shown in FIGS. 3 to 5, the drive back plate 10 further includes a reflective structure 17. The reflective structure 17 is distributed along the sidewall of the accommodation hole 16. The orthographic projection of the reflective structure 17 on the base substrate 11 surrounds the orthographic projection of the bonding structure 13 on the base substrate 11. The reflective structure 17 can reflect light emitted by the light-emitting device in the accommodation hole 16, such that the light emitted by the light-emitting device may be converged, and more light can be emitted from the direction of the front viewing angle, thereby improving the utilization ratio of light and the brightness of the front viewing angle.

In an optional embodiment, the orthographic projection of the reflective structure 17 on the base substrate 11 is of a closed ring shape. The reflective structure 17 may cover the sidewall of the accommodation hole 16, such that the reflective structure 17 may fully concentrate the light emitted by the light-emitting device. The shape of the orthographic projection of the reflective structure 17 on the base substrate 11 is determined based on the structure of the accommodation hole 16. For example, the cross section of the accommodation hole 16 is of a rectangle shape, the orthographic projection of the reflective structure 17 on the base substrate 11 is of a closed ring shape, and the inner ring and the outer ring of the closed ring may be both rectangular. For another example, the cross section of the accommodation hole 16 is of a circle shape, and the orthographic projection of the reflective structure 17 on the base substrate 11 is of a circular ring shape. The orthographic projection of the reflective structure 17 on the base substrate 11 may also be of a semi-closed ring shape, which is not limited in the embodiments of the present disclosure.

In an optional embodiment, as shown in FIG. 3, the accommodation hole 16 penetrates through the protective layer 15, the second ILD layer 12262, the first ILD layer 12261, the second GI layer 1224 and the first GI layer 1222. The reflective structure 17 is extended from the side of the protective layer 15 away from the base substrate 11 to the base substrate 11 along the sidewall of the accommodation hole 16. For example, the reflective structure 17 is extended from the side of the protective layer 15 away from the base substrate 11 to the buffer layer 14 along the sidewall of the accommodation hole 16. For the drive back plate 10 shown in FIG. 3, a guard layer (not shown in FIG. 3) may also be formed on the side of the protective layer 15 away from the base substrate 11, such that the guard layer covers the reflective structure 17. Thus, the guard layer can protect the reflective structure 17, to prevent the reflective structure 17 from being oxidized.

In another optional embodiment, as shown in FIG. 4, the accommodation hole 16 penetrates through the second ILD layer 12262, the first ILD layer 12261, the second GI layer 1224 and the first GI layer 1222. The reflective structure 17 is extended from the side of the second ILD layer 12262 away from the base substrate 11 to the base substrate 11 along the sidewall of the accommodation hole 16. For example, the reflective structure 17 is extended from the side of the second ILD layer 12262 away from the base substrate 11 to the buffer layer 14 along the sidewall of the accommodation hole 16. The protective layer 15 is extended into the accommodation hole 16 along the surface, away from the sidewall of the accommodation hole 16, of the reflective structure 17 and covers the reflective structure 17. That is, the protective layer 15 is recessed at the position of the accommodation hole 16, so as to cover the reflective structure 17, but the protective layer 15 does not cover the bonding structure 13. For the drive back plate 10 shown in FIG. 4, the material of the reflective structure 17 may be the same as the material of the source-drain layer. The reflective structure 17 and the source-drain layer may be manufactured through one-time patterning process, which can simplify the manufacturing process of the drive back plate 10 and reducing the production cost.

In an optional embodiment, the drive circuit 12 further includes signal lines such as a power line, a data line, and a scan line. The power line is configured to provide a power signal to the drive circuit 12 such that the drive circuit 12 operates. The data line may be electrically connected to the source 1227 of the switch unit 122. The data line is configured to provide a data signal to the source 1227 of the switch unit 122. The scan line may also be referred to as a gate line. The scan line may be electrically connected to the gate (e.g., the first gate 1221) of the switch unit 122. The scan line is configured to provide a switch signal to the switch unit. At least one signal line may be disposed on the same layer as the first gate 1221, such that the at least one signal line and the first gate 1221 may be manufactured through one-time patterning process, which simplifies the manufacturing process of the drive back plate 10. For example, as shown in FIGS. 1 to 5, the drive circuit 12 further includes a positive power line 125, a negative power line 126 and a gate line 127. The positive power line 125 and the negative power line 126 may be disposed on the same layer as the first gate 1221. The gate line 127 and the second gate 1225 may be disposed on the same layer. The positive power line 125 may be electrically connected to the source 1227 of the switch unit 122 (for example, the positive power line 125 is electrically connected to the source 1227 of the switch unit 122 through the data line, which is not shown in FIGS. 1 to 5). The negative power line 126 may be electrically connected to the second bonding portion 132 (for example, the negative power line 126 and the second bonding portion 132 are of an integral structure). The drain 1228 of the switch unit 122 may be electrically connected to the first bonding portion 131. In this way, after the first electrode of the light-emitting device is bonded to the first bonding portion 131 and the second electrode of the light-emitting device is bonded to the second bonding portion 132, the light-emitting device is connected between the positive power line 125 and the negative power line 126.

FIG. 1 to FIG. 5 only exemplarily show the structures of the drive back plate. The drive back plate may also be of other structures in addition to the structures shown in the drawings. The structure of the drive back plate is not limited in the embodiments of the present disclosure.

In summary, in the drive back plate according to the embodiment of the present disclosure, the bonding structure and the target drive structure are disposed on the same layer, and the film layer in contact with the target drive structure is an inorganic insulating layer. Therefore, in the process of manufacturing the drive back plate, the film layer in contact with the bonding structure is an inorganic insulating layer, and the inorganic insulating layer can prevent the bonding structure from being oxidized. Since the bonding structure and the target drive structure may be manufactured through the one-time patterning process, the manufacturing process of the drive back plate can be simplified and the production cost of the drive back plate can be reduced. For example, the drive back plate shown in FIG. 1 or FIG. 4 may be manufactured through 8 times of patterning processes, and the drive back plate shown in FIG. 3 may be manufactured through 9 times of patterning processes, while at least 14 times of patterning processes are required for manufacturing the current drive back plate. It can be seen that, compared with the current drive back plate, at least 5 times of patterning processes are reduced in the manufacturing process of the drive back plate according to the embodiment of the present disclosure.

The drive back plate according to the present disclosure is described above, and a method for manufacturing a drive back plate is described below. For the manufacturing method and manufacturing principle of the drive back plate, reference may be made to the descriptions in the following embodiments.

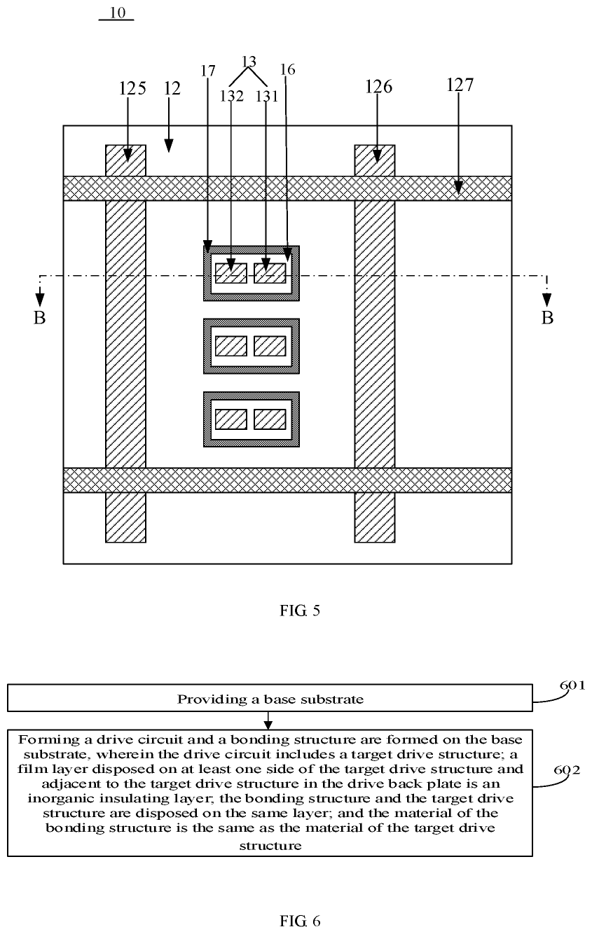

FIG. 6 is a flowchart of a method for manufacturing a drive back plate according to an embodiment of the present disclosure. This method may be applicable to manufacture the drive back plate in the above embodiments. As shown in FIG. 6, the method includes the following steps.

In step 601, a base substrate is provided.

In step 602, a drive circuit and a bonding structure are formed on the base substrate. The drive circuit includes a target drive structure. A film layer disposed on at least one side of the target drive structure and adjacent to the target drive structure in the drive back plate is an inorganic insulating layer. The bonding structure and the target drive structure are disposed on the same layer, and the material of the bonding structure is the same as the material of the target drive structure.

Optionally, forming the drive circuit on the base substrate includes forming at least one of a switch unit and a storage capacitor on the base substrate. The target drive structure may include any one of a functional structure of the switch unit, and a plate of the storage capacitor. For example, functional structures of the switch unit include a gate, an active layer, a source and a drain, and the target drive structure is the gate of the switch unit.

In summary, in the drive back plate manufactured by the method according to the embodiment of the present disclosure, the bonding structure and the target drive structure are disposed on the same layer, and the film layer in contact with the target drive structure is an inorganic insulating layer. Therefore, in the process of manufacturing the drive back plate, the film layer in contact with the bonding structure is an inorganic insulating layer, and the inorganic insulating layer can prevent the bonding structure from being oxidized. Since the bonding structure and the target drive structure may be manufactured through the one-time patterning process, the manufacturing process of the drive back plate can be simplified and the production cost of the drive back plate can be reduced.

In the embodiment of the present disclosure, the switch unit may be a bottom-gate TFT, a top-gate TFT or a double-gate TFT. The drive back plate further includes a protective layer, an accommodation hole, a reflective structure, and the like. The method for manufacturing the drive back plate according to the present disclosure is described hereinafter in three embodiments by taking example in which the switch unit is a double-gate TFT and according to different positional relationships among the protective layer, the accommodation hole and the reflective structure.

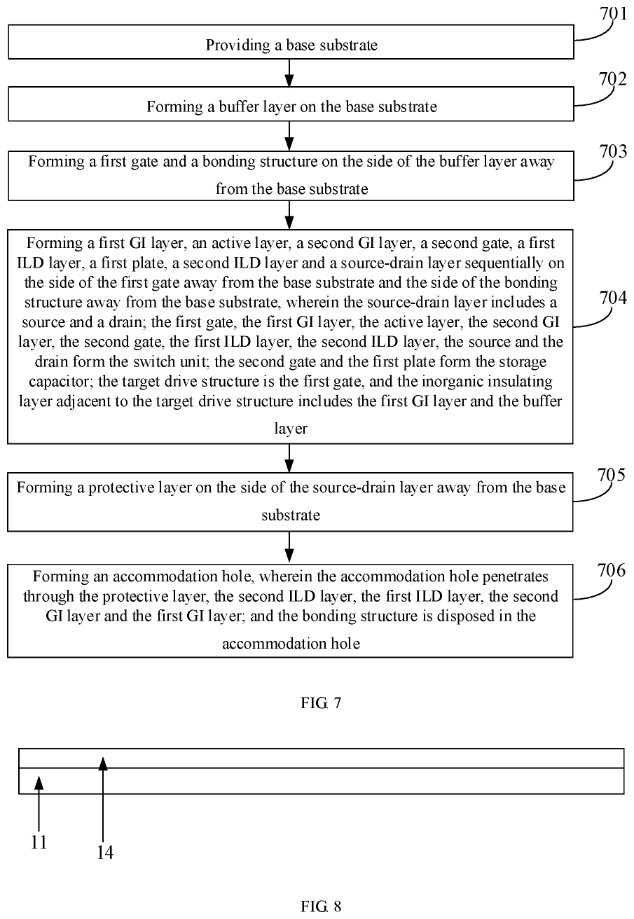

FIG. 7 is a flowchart of another method for manufacturing a drive back plate according to an embodiment of the present disclosure. FIG. 7 illustrates the manufacture of the drive back plate 10 shown in FIG. 1. As shown in FIG. 7, the method includes the following steps.

In step 701, a base substrate is provided.

The base substrate is a rigid substrate or a flexible substrate. For example, the base substrate is a rigid substrate made of a material with certain rigidness, such as glass, quartz, or transparent resin. Alternatively, the base substrate is a flexible substrate made of a flexible material such as PI.

In step 702, a buffer layer is formed on the base substrate.

FIG. 8 is a schematic diagram after the buffer layer 14 is formed on the base substrate 11 according to an embodiment of the present disclosure. The buffer layer 14 is disposed on a side of the base substrate 11, and the buffer layer 14 covers the base substrate 11.

The material of the buffer layer 14 may be an inorganic insulating material such as silicon oxide and silicon nitride. For example, a layer of silicon oxide is deposited on the base substrate 11 as the buffer layer 14.

In step 703, a first gate and a bonding structure are formed on the side of the buffer layer away from the base substrate.

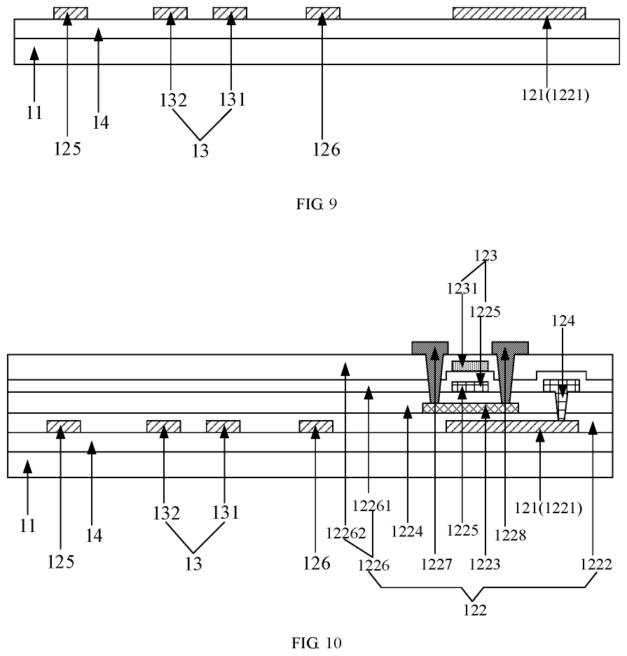

FIG. 9 is a schematic diagram after the first gate 1221 and the bonding structure 13 are formed on the side of the buffer layer 14 away from the base substrate 11 according to an embodiment of the present disclosure. The bonding structure 13 includes a first bonding portion 131 and a second bonding portion 132. The first bonding portion 131, the second bonding portion 132 and the first gate 1221 are arranged at intervals.

Both the material of the bonding structure 13 and the material of the first gate 1221 may be metal, such as copper. For example, a copper material layer is formed on the side of the buffer layer 14 away from the base substrate 11, and the one-time patterning process is performed on the copper material layer to obtain the first bonding portion 131, the second bonding portion 132 and the first gate 1221.

In the embodiment of the present disclosure, the drive back plate further includes a positive power line 125 and a negative power line 126. Both the positive power line 125 and the negative power line 126 are disposed on the same layer as the first gate 1221. In the process of forming the first gate 1221 and the bonding structure 13, the positive power line 125 and the negative power line 126 may also be formed.

In step 704, a first GI layer, an active layer, a second GI layer, a second gate, a first ILD layer, a first plate, a second ILD layer and a source-drain layer are sequentially formed on the side of the first gate away from the base substrate and the side of the bonding structure away from the base substrate. The source-drain layer includes a source and a drain. The first gate, the first GI layer, the active layer, the second GI layer, the second gate, the first ILD layer, the second ILD layer, the source and the drain form the switch unit. The second gate and the first plate form the storage capacitor. The target drive structure is the first gate, and the inorganic insulating layer adjacent to the target drive structure includes the first GI layer and the buffer layer.

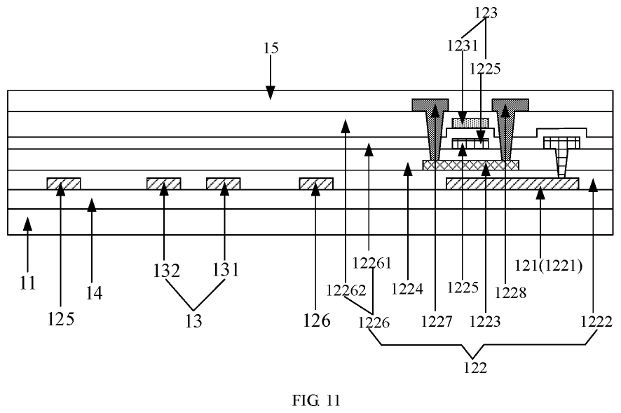

FIG. 10 shows a schematic diagram after the first GI layer 1222, the active layer 1223, the second GI layer 1224, the second gate 1225, the first ILD layer 12261, the first plate 1231, the second ILD layer 12262 and the source-drain layer are formed on the side of the first gate 1221 away from the base substrate 11 and the side of the bonding structure 13 away from the base substrate 11 according to an embodiment of the present disclosure. The source-drain layer includes the source 1227 and the drain 1228. Each of the second ILD layer 12262, the first ILD layer 12261 and the second GI layer 1224 is provided with a source via and a drain via. The source 1227 is electrically connected to the active layer 1223 through the source via. The drain 1228 is electrically connected to the active layer 1223 through the drain via. The second gate 1225 is electrically connected to the first gate 1221 through the connection structure 124. The first gate 1221, the first GI layer 1222, the active layer 1223, the second GI layer 1224, the second gate 1225, the first ILD layer 12261, the second ILD layer 12262, the source 1227 and the drain 1228 form the switch unit 122. The second gate 1225 and the first plate 1231 form the storage capacitor 123.

The material of the first GI layer 1222, the material of the second GI layer 1224, the material of the first ILD layer 12261 and the material of the second ILD layer 12262 may all be an inorganic insulating material such as silicon oxide and silicon nitride. The material of the active layer 1223 may be polysilicon, amorphous silicon or metal oxide. Both the material of the second gate 1225 and the material of the first plate 1231 may be metal. The source-drain layer may include a first metal layer, a second metal layer and a third metal layer that are laminated sequentially along the direction going away from the base substrate 11. The material of the first metal layer and the material of the third metal layer may both be titanium, and the material of the second metal layer may be aluminum.

For example, step 704 includes the following sub-steps.

In sub-step 1, a layer of silicon oxide is deposited as the first GI layer 1222 on the side of the first gate 1221 away from the base substrate 11 and the side of the bonding structure 13 away from the base substrate 11.

In sub-step 2, a polysilicon material layer is formed on the side of the first GI layer 1222 away from the base substrate 11, and the one-time patterning process is performed on the polysilicon material layer to obtain the active layer 1223.

In sub-step 3, a layer of silicon oxide is deposited as the second GI layer 1224 on the side of the active layer 1223 away from the base substrate 11.

In sub-step 4, a connection hole a is formed in the second GI layer 1224 and the first GI layer 1222 through the one-time patterning process, and the connection hole a penetrates through the second GI layer 1224 and the first GI layer 1222. A portion of the first gate 1221 is exposed from the connection hole a.

In sub-step 5, a metal material layer is formed on the side of the second GI layer 1224 away from the base substrate 11, and the one-time patterning process is performed on the metal material layer to obtain the second gate 1225 and the connection structure 124. The connection structure 124 is electrically connected to the second gate 1225, and the connection structure 124 is electrically connected to the first gate 1121 through the connection hole a.

In sub-step 6, a layer of silicon nitride is deposited as the first ILD layer 12261 on the side of the second gate 1225 away from the base substrate 11 and the side of the connection structure 124 away from the base substrate 11.

In sub-step 7, a metal material layer is formed on the side of the first ILD layer 12261 away from the base substrate 11, and the one-time patterning process is performed on the metal material layer to obtain the first plate 1231.

In sub-step 8, a layer of silicon nitride is deposited as the second ILD layer 12262 on the side of the first plate 1231 away from the base substrate 11.

In sub-step 9, a source via b and a drain via c are formed in the second ILD layer 12262, the first ILD layer 12261 and the second GI layer 1224 through the one-time patterning process.

In sub-step 10, a first metal material layer, a second metal material layer and a third metal material layer are sequentially formed on the side of the second ILD layer 12262 away from the base substrate 11, and the one-time patterning process is performed on the first metal material layer, the second metal material layer and the third metal material layer to obtain the source 1127 and the drain 1128. The source 1127 and the drain 1128 both include the first metal layer, the second metal layer and the third metal layer which are laminated sequentially.

In step 705, a protective layer is formed on the side of the source-drain layer away from the base substrate.

FIG. 11 is a schematic diagram after the protective layer 15 is formed on the side of the source-drain layer away from the base substrate 11 according to an embodiment of the present disclosure. The protective layer 15 covers the source-drain layer and the second ILD layer 12262.

The protective layer 15 may be of a single-layered structure or a multi-layered structure. For example, the protective layer 15 includes a PVX layer and a PLN layer laminated along a direction away from the base substrate 11. The material of the PVX layer may be an inorganic insulating material such as silicon oxide and silicon nitride, or an organic resin material. The material of the PLN layer may be an organic resin material. Forming the protective layer 15 on the side of the source-drain layer away from the base substrate 11 may include: firstly depositing a layer of silicon nitride as the PVX layer on the side of the source-drain layer away from the base substrate 11, and then coating a layer of organic resin material as the PLN layer on the side of the PVX layer away from the base substrate 11.

In step 706, an accommodation hole is formed. The accommodation hole penetrates through the protective layer, the second ILD layer, the first ILD layer, the second GI layer and the first GI layer. The bonding structure is disposed in the accommodation hole.

The schematic diagram after the accommodation hole 16 is formed is shown in FIG. 1. The accommodation hole 16 penetrates through the protective layer 15, the second ILD layer 12262, the first ILD layer 12261, the second GI layer 1224 and the first GI layer 1222. The bonding structure 13 is disposed in the accommodation hole 16. For example, the bottom surface of the accommodation hole 16 is the side of the buffer layer 14 away from the base substrate 11, and the bonding structure 13 is disposed on the bottom surface of the accommodation hole 16.

For example, the accommodation hole 16 penetrating through the protective layer 15, the second ILD layer 12262, the first ILD layer 12261, the second GI layer 1224 and the first GI layer 1222 is formed through the one-time patterning process.

It can be known from the descriptions of step 702 to step 706 that before step 706 is performed, the bonding structure 13 is wrapped by the buffer layer 14 and the first GI layer 1222, and the buffer layer 14 and the first GI layer 1222 are both inorganic insulating layers. Therefore, the buffer layer 14 and the first GI layer 1222 can prevent the bonding structure 13 from being oxidized.

In summary, in the process of manufacturing the drive back plate by the method according to the embodiment of the present disclosure, the bonding structure is wrapped by the buffer layer and the first GI layer, and the buffer layer and the first GI layer are both inorganic insulating layers. Therefore, the buffer layer and the first GI layer can prevent the bonding structure from being oxidized. Since the bonding structure and the first gate (i.e., the target drive structure) are manufactured through the one-time patterning process, the manufacturing process of the drive back plate can be simplified and the production cost of the drive back plate can be reduced.

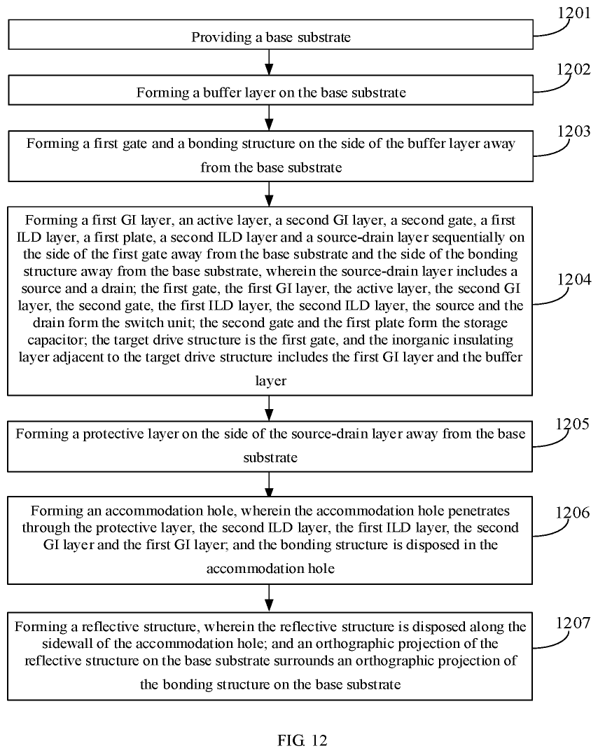

FIG. 12 is a flowchart of still another method for manufacturing a drive back plate according to an embodiment of the present disclosure. FIG. 12 illustrates the manufacture of the drive back plate 10 shown in FIG. 3. As shown in FIG. 12, the method includes the following steps.

In step 1201, a base substrate is provided.

In step 1202, a buffer layer is formed on the base substrate.

In step 1203, a first gate and a bonding structure are formed on the side of the buffer layer away from the base substrate.

In step 1204, a first GI layer, an active layer, a second GI layer, a second gate, a first ILD layer, a first plate, a second ILD layer and a source-drain layer are sequentially formed on the side of the first gate away from the base substrate and the side of the bonding structure away from the base substrate. The source-drain layer includes a source and a drain. The first gate, the first GI layer, the active layer, the second GI layer, the second gate, the first ILD layer, the second ILD layer, the source and the drain form the switch unit. The second gate and the first plate form the storage capacitor. The target drive structure is the first gate, and the inorganic insulating layer adjacent to the target drive structure includes the first GI layer and the buffer layer.

In step 1205, a protective layer is formed on the side of the source-drain layer away from the base substrate.

In step 1206, an accommodation hole is formed. The accommodation hole penetrates through the protective layer, the second ILD layer, the first ILD layer, the second GI layer and the first GI layer. The bonding structure is disposed in the accommodation hole.

For the implementation process of steps 1201 to 1206, reference may be made to steps 701 to 706, which is not repeated in this embodiment. The drive back plate obtained after steps 1201 to 1206 is shown in FIG. 1.

In step 1207, a reflective structure is formed. The reflective structure is disposed along the sidewall of the accommodation hole. An orthographic projection of the reflective structure on the base substrate surrounds an orthographic projection of the bonding structure on the base substrate.

The schematic diagram after the reflective structure 17 is formed is shown FIG. 3. The reflective structure 17 is distributed along the sidewall of the accommodation hole 16, and the orthographic projection of the reflective structure 17 on the base substrate 11 surrounds the orthographic projection of the bonding structure 13 on the base substrate 11. For example, the reflective structure 17 covers the sidewall of the accommodation hole 16, and the orthographic projection of the reflective structure 17 on the base substrate 11 is of a closed ring shape. As shown in FIG. 3, the reflective structure 17 is extended from the side of the protective layer 15 away from the base substrate 11 to the buffer layer 14 along the sidewall of the accommodation hole 16.

For example, a metal material layer is formed on the side of the protective layer 15 away from the base substrate 11, and the one-time patterning process is performed on the metal material layer to obtain the reflective structure 17.

It can be known from the descriptions of step 1202 to step 1207 that, before step 1206 is performed, the bonding structure 13 is wrapped by the buffer layer 14 and the first GI layer 1222, and the buffer layer 14 and the first GI layer 1222 are both inorganic insulating layers. Therefore, the buffer layer 14 and the first GI layer 1222 can prevent the bonding structure 13 from being oxidized.

In summary, in the process of manufacturing the drive back plate by the method according to the embodiment of the present disclosure, the bonding structure is wrapped by the buffer layer and the first GI layer, and the buffer layer and the first GI layer are both inorganic insulating layers. Therefore, the buffer layer and the first GI layer can prevent the bonding structure from being oxidized. Since the bonding structure and the first gate (i.e., the target drive structure) are manufactured through the one-time patterning process, the manufacturing process of the drive back plate can be simplified and the production cost of the drive back plate can be reduced.

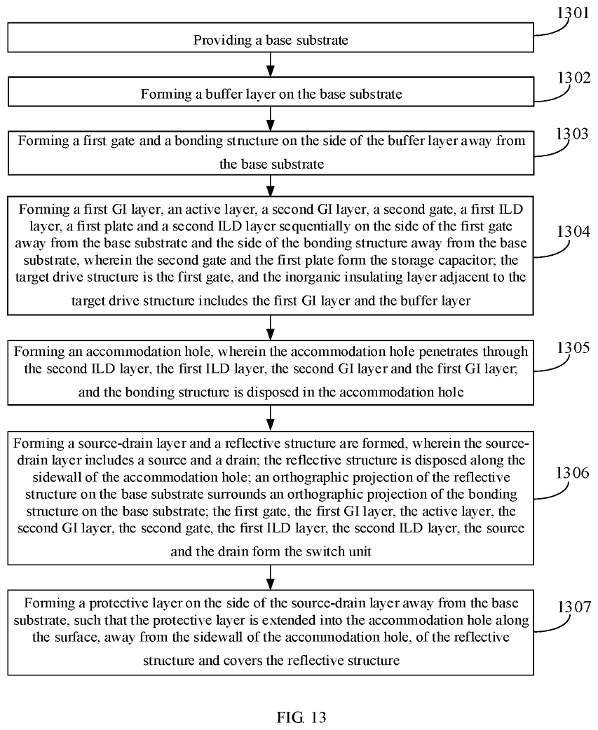

FIG. 13 is a flowchart of still another method for manufacturing a drive back plate according to an embodiment of the present disclosure. FIG. 13 illustrates the manufacture of the drive back plate 10 shown in FIG. 4. As shown in FIG. 13, the method includes the following steps.

In step 1301, a base substrate is provided.

In step 1302, a buffer layer is formed on the base substrate.

In step 1303, a first gate and a bonding structure are formed on the side of the buffer layer away from the base substrate.

For the implementation process of steps 1301 to 1303, reference may be made to the above steps 701 to 703, and details are not described herein again in this embodiment.

In step 1304, a first GI layer, an active layer, a second GI layer, a second gate, a first ILD layer, a first plate and a second ILD layer are sequentially formed on the side of the first gate away from the base substrate and the side of the bonding structure away from the base substrate. The second gate and the first plate form the storage capacitor. The target drive structure is the first gate, and the inorganic insulating layer adjacent to the target drive structure includes the first GI layer and the buffer layer.

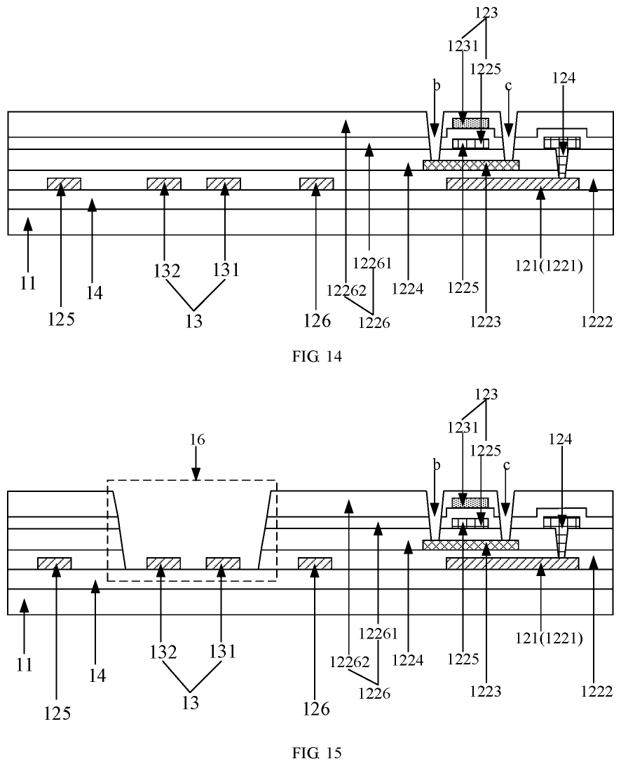

FIG. 14 shows a schematic diagram after the first GI layer 1222, the active layer 1223, the second GI layer 1224, the second gate 1225, the first ILD layer 12261, the first plate 1231 and the second ILD layer 12262 are formed on the side of the first gate 1221 away from the base substrate 11 and the side of the bonding structure 13 away from the base substrate 11 according to an embodiment of the present disclosure. The second ILD layer 12262, the first ILD layer 12261 and the second GI layer 1224 each have a source via b and a drain via c. The second gate 1225 is electrically connected to the first gate 1221 through the connection structure 124. The second gate 1225 and the first plate 1231 form the storage capacitor 123.

For example, step 1304 includes the following sub-steps.

In sub-step 1, a layer of silicon oxide is deposited as the first GI layer 1222 on the side of the first gate 1221 away from the base substrate 11 and the side of the bonding structure 13 away from the base substrate 11.

In sub-step 2, a polysilicon material layer is formed on the side of the first GI layer 1222 away from the base substrate 11, and the one-time patterning process is performed on the polysilicon material layer to obtain the active layer 1223.

In sub-step 3, a layer of silicon oxide is deposited as the second GI layer 1224 on the side of the active layer 1223 away from the base substrate 11.

In sub-step 4, a connection hole a is formed in the second GI layer 1224 and the first GI layer 1222 through the one-time patterning process, and the connection hole a penetrates through the second GI layer 1224 and the first GI layer 1222. A portion of the first gate 1221 is exposed from the connection hole a.

In sub-step 5, a metal material layer is formed on the side of the second GI layer 1224 away from the base substrate 11, and the one-time patterning process is performed on the metal material layer to obtain the second gate 1225 and the connection structure 124. The connection structure 124 is electrically connected to the second gate 1225, and the connection structure 124 is electrically connected to the first gate 1121 through the connection hole a.

In sub-step 6, a layer of silicon nitride is deposited as the first ILD layer 12261 on the side of the second gate 1225 away from the base substrate 11 and the side of the connection structure 124 away from the base substrate 11.

In sub-step 7, a metal material layer is formed on the side of the first ILD layer 12261 away from the base substrate 11, and the one-time patterning process is performed on the metal material layer to obtain the first plate 1231.

In sub-step 8, a layer of silicon nitride is deposited as the second ILD layer 12262 on the side of the first plate 1231 away from the base substrate 11.

In sub-step 9, a source via b and a drain via c are formed in the second ILD layer 12262, the first ILD layer 12261 and the second GI layer 1224 through the one-time patterning process.

In step 1305, an accommodation hole is formed. The accommodation hole penetrates through the second ILD layer, the first ILD layer, the second GI layer and the first GI layer. The bonding structure is disposed in the accommodation hole.

FIG. 15 is a schematic diagram after the accommodation hole 16 is formed according to an embodiment of the present disclosure. The accommodation hole 16 penetrates through the second ILD layer 12262, the first ILD layer 12261, the second GI layer 1224 and the first GI layer 1222. The bonding structure 13 is disposed in the accommodation hole 16. For example, the bottom surface of the accommodation hole 16 is the side of the buffer layer 14 away from the base substrate 11, and the bonding structure 13 is disposed on the bottom surface of the accommodation hole 16.

For example, the accommodation hole 16 penetrating through the second ILD layer 12262, the first ILD layer 12261, the second GI layer 1224 and the first GI layer 1222 is formed through the one-time patterning process.

In step 1306, a source-drain layer and a reflective structure are formed. The source-drain layer includes a source and a drain. The reflective structure is distributed along the sidewall of the accommodation hole. An orthographic projection of the reflective structure on the base substrate surrounds an orthographic projection of the bonding structure on the base substrate. The first gate, the first GI layer, the active layer, the second GI layer, the second gate, the first ILD layer, the second ILD layer, the source and the drain form the switch unit.

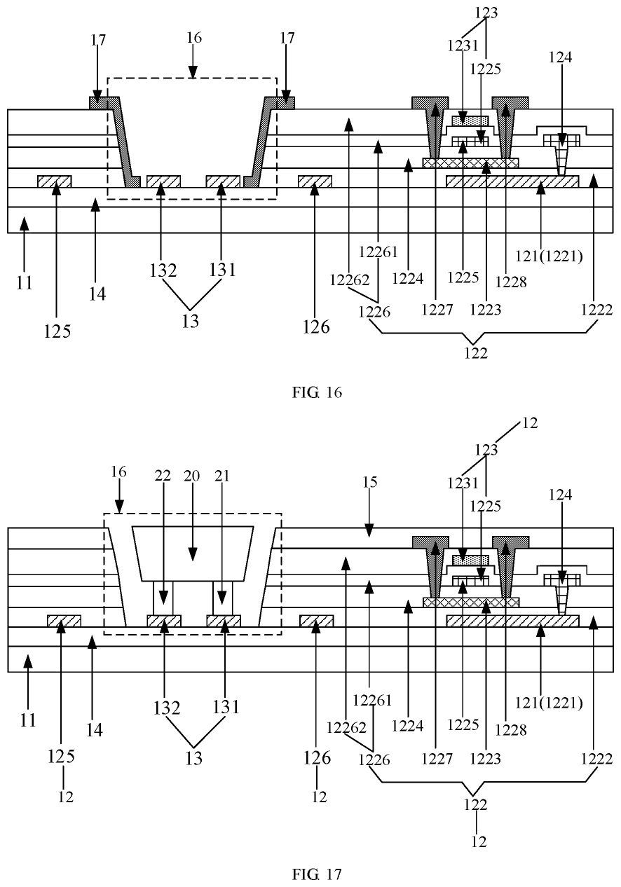

FIG. 16 is a schematic diagram after the source-drain layer and the reflective structure 17 are formed according to an embodiment of the present disclosure. The source-drain layer includes the source 1227 and the drain 1228. The source 1227 is electrically connected to the active layer 1223 through the source via b. The drain 1228 is electrically connected to the active layer 1223 through the drain via c. The first gate 1221, the first GI layer 1222, the active layer 1223, the second GI layer 1224, the second gate 1225, the first ILD layer 12261, the second ILD layer 12262, the source 1227 and the drain 1228 form the switch unit 122. The reflective structure 17 is distributed along the sidewall of the accommodation hole 16. The orthographic projection of the reflective structure 17 on the base substrate 11 surrounds the orthographic projection of the bonding structure 13 on the base substrate 11. The reflective structure 17 is extended from the side of the second ILD layer 12262 away from the base substrate 11 to the buffer layer 14 along the sidewall of the accommodation hole 16.

The material of the source-drain layer and the material of the reflective structure 17 may be metal. Both the source-drain layer and the reflective structure 17 may include a first metal layer, a second metal layer and a third metal layer that are laminated sequentially. The material of the first metal layer and the material of the third metal layer may both be titanium, and the material of the second metal layer may be aluminum. For example, the first metal material layer, the second metal material layer and the third metal material layer are sequentially formed on the side of the second ILD layer 12262 away from the base substrate 11, and the first metal material layer, the second metal material layer and the third metal material layer are processed through the one-time patterning process to obtain the source 1127, the drain 1128 and the reflective structure 17.

In step 1307, a protective layer is formed on the side of the source-drain layer away from the base substrate, such that the protective layer is extended into the accommodation hole along the surface, away from the sidewall of the accommodation hole, of the reflective structure and covers the reflective structure.

FIG. 4 shows the schematic diagram after the protective layer 15 is formed on the side of the source-drain layer away from the base substrate 11. The protective layer 15 covers the source-drain layer and the second ILD layer 12262. The protective layer 15 is extended into the accommodation hole 16 along the surface, away from the sidewall of the accommodation hole 16, of the reflective structure 17 and covers the reflective structure 17.

The protective layer 15 may be of a single-layered structure or a multi-layered structure. For example, the protective layer 15 includes a PVX layer and a PLN layer laminated along the direction away from the base substrate 11. The material of the PVX layer may be an inorganic insulating material such as silicon oxide and silicon nitride, or an organic resin material. The material of the PLN layer may be an organic resin material. Forming the protective layer 15 on the side of the source-drain layer away from the base substrate 11 may include: firstly forming a silicon nitride material layer on the side of the source-drain layer away from the base substrate 11; forming an organic resin layer on the side of the silicon nitride material layer away from the base substrate 11; and then performing the one-time patterning process on the organic resin layer and the silicon nitride material layer to obtain the laminated PVX layer and PLN layer, that is, to obtain the protective layer 15.

From the descriptions of steps 1302 to 1305, it can be known that before step 1305 is performed, the bonding structure 13 is wrapped by the buffer layer 14 and the first GI layer 1222, and the buffer layer 14 and the first GI layer 1222 are both inorganic insulating layers. Therefore, the buffer layer 14 and the first GI layer 1222 can prevent the bonding structure 13 from being oxidized.

In summary, in the process of manufacturing the drive back plate by the method according to the embodiment of the present disclosure, the bonding structure is wrapped by the buffer layer and the first GI layer, and the buffer layer and the first GI layer are both inorganic insulating layers. Therefore, the buffer layer and the first GI layer can prevent the bonding structure from being oxidized. Since the bonding structure and the first gate (i.e., the target drive structure) are manufactured through the one-time patterning process, the manufacturing process of the drive back plate can be simplified and the production cost of the drive back plate can be reduced.

In the embodiments of the present disclosure, the material layer may be formed through deposition, magnetron sputtering, thermal evaporation, or the like, for example, a plasma enhanced chemical vapor deposition (PECVD) process. For example, in step 703, a copper material layer may be formed on the side of the buffer layer 14 away from the base substrate 11 by any one of deposition, magnetron sputtering, and thermal evaporation. In addition, the one-time patterning process in the embodiments of the present disclosure includes photoresist coating, exposure, development, etching, and photoresist stripping. Performing the one-time patterning on the material layer (e.g., the copper material layer) includes: coating a layer of photoresist on the material layer (e.g., the copper material layer) to form a photoresist layer; performing exposure on the photoresist layer with a mask, such that a fully-exposed region and a non-exposed region are formed on the photoresist layer; performing a developing process to completely remove the photoresist in the fully-exposed region, and completely retain the photoresist in the non-exposed region; and etching the region, corresponding to the fully-exposed region, of the material layer (such as the copper material layer) through an etching process; and stripping off the photoresist in the non-exposed region to obtain corresponding structures (e.g., the first bonding portion 131, the second bonding portion 132 and the first gate 1221). Here, illustration is provided by taking an example in which the photoresist is positive photoresist. When the photoresist is negative photoresist, for the process of the one-time patterning process, reference may be made to the descriptions in this paragraph, and details are not repeated in the embodiments of the present disclosure.

Although steps of the manufacturing method according to the present disclosure are described in a particular order in the drawings, it does not require or imply that the steps must be performed in that particular order, or that all of the steps shown must be performed to achieve a desired result. Additionally or alternatively, certain steps may be omitted, a plurality of steps may be combined into one step for execution, and/or one step may be divided into a plurality of steps for execution, and the like. In the method for manufacturing a drive back plate according to the embodiments of the present disclosure, the sequence of steps may be adjusted appropriately, and the steps may also be added or removed according to situations. Within the technical scope disclosed in the present disclosure, all variations to the methods derived by persons skilled in the art shall be included in the protection scope of the present disclosure.

The above descriptions introduce the method for manufacturing a drive back plate according to the present disclosure. Based on the same inventive concept, an embodiment of the present disclosure further provides a display panel. An embodiment of the display panel is described below.

An embodiment of the present disclosure provides a display panel. The display panel includes a light-emitting device and the drive back plate 10 according to any of the above embodiments. The light-emitting device is bonded to the bonding structure 13 in the drive back plate 10. The drive circuit 12 in the drive back plate 10 is configured to drive the light-emitting device to emit light.

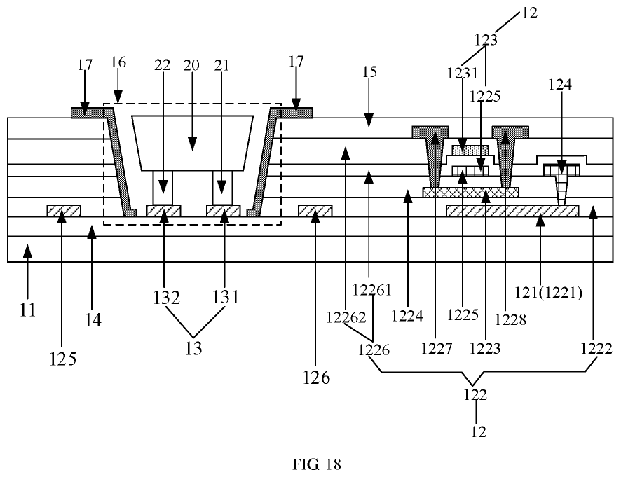

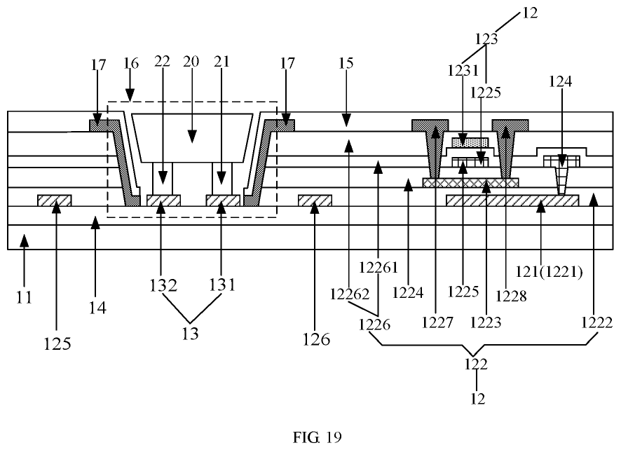

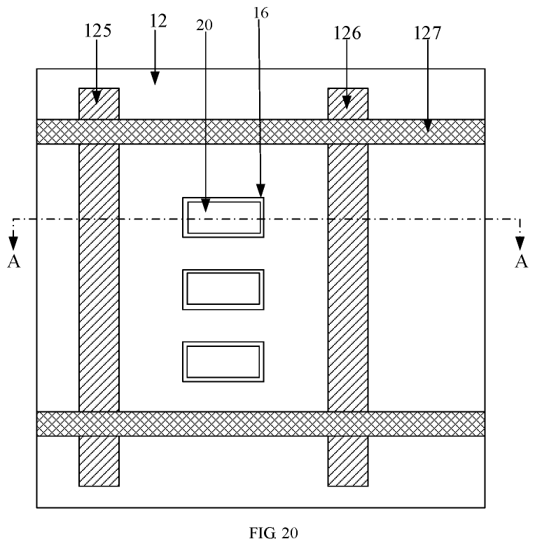

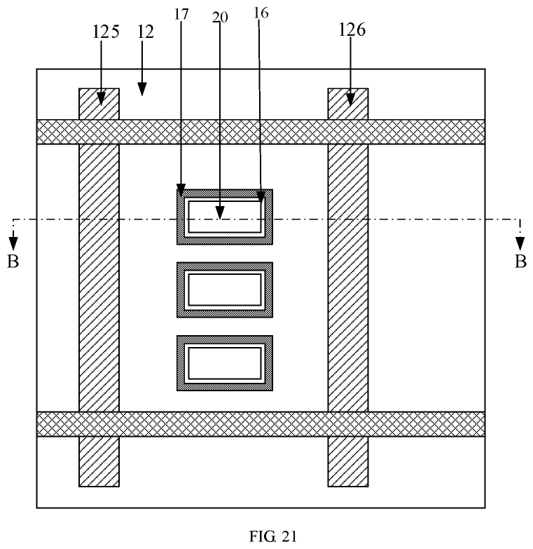

For example, a sectional view of the display panel may be as shown in any of FIG. 17 to FIG. 19. A partial front view of the display panel may be shown in FIG. 20 or FIG. 21. FIG. 17 may be a sectional view of portion A-A in FIG. 20. FIG. 18 or FIG. 19 may be a sectional view of portion B-B of FIG. 21. As shown in FIG. 17 to FIG. 21, the light-emitting device 20 includes a first electrode 21 and a second electrode 22. The light-emitting device 20 is disposed in the accommodation hole 16 of the drive back plate 10. The first electrode 21 is bonded to the first bonding portion 131 of the drive back plate 10, and the second electrode 22 is bonded to the second bonding portion 132 of the drive back plate 10. For example, the first electrode 21 is attached and welded to the first bonding portion 131, such that the first electrode 21 is bonded to the first bonding portion 131. The second electrode 22 is attached and welded to the second bonding portion 132, such that the second electrode 22 is bonded to the second bonding portion 132.

FIG. 17 to FIG. 21 only exemplarily show the structure of the display panel. In practice, the display panel includes a plurality of light-emitting devices 20, the drive back plate 10 includes a plurality of accommodation holes 16, and each accommodation hole 16 is provided with a light-emitting device 20. The light-emitting device 20 may be an LED chip, for example, a Micro LED chip or a Mini LED chip. The colors of the plurality of light-emitting devices 20 in the display panel may not all be the same. For example, the light-emitting devices 20 in the display panel include a red LED chip (an LED chip which emits red light), a blue LED chip (an LED chip which emits blue light), and a green LED chip (an LED chip which emits green light).

An embodiment of the present disclosure further provides a display device, which includes the above display panel. For example, the display device may be a product or a component with an image display function such as a mobile phone, a tablet computer, a notebook computer, a TV, electronic paper, a display, a navigator, a digital photo frame, a virtual reality (VR) device, an augmented reality (AR) device, a wearable device, or the like.

Other embodiments of the present disclosure may be readily derived by those skilled in the art upon consideration of the description and practice of the present disclosure. The present disclosure is intended to cover any variations, uses or adaptations of the present disclosure that follow the general principles of the present disclosure and include common knowledge or conventional technical means in the technical field which are not disclosed in the present disclosure. The description and embodiments are considered as examples only, and the true scope and spirit of the present disclosure are indicated by the appended claims.

What is claimed is:

1. A drive back plate, comprising:
a base substrate, and a drive circuit and a bonding structure disposed on the base substrate, wherein
the drive circuit comprises a target drive structure, and a film layer disposed on at least one side of the target drive structure and adjacent to the target drive structure in the drive back plate is an inorganic insulating layer; and
the bonding structure and the target drive structure are disposed on a same layer, and a material of the bonding structure is the same as a material of the target drive structure.

2. The drive back plate according to claim 1, wherein
the drive circuit comprises at least one of a switch unit and a storage capacitor; and
the target drive structure comprises any one of a functional structure of the switch unit and a plate of the storage capacitor.

3. The drive back plate according to claim 1, wherein
the drive circuit comprises a switch unit, functional structures of the switch unit comprising a gate, an active layer, a source and a drain; and
the target drive structure is the gate of the switch unit.

4. The drive back plate according to claim 3, wherein
the switch unit comprises a first gate, a first gate insulating layer, an active layer, a second gate insulating layer, a second gate, an interlayer dielectric layer and a source-drain layer which are sequentially disposed along a direction going away from the base substrate, the source-drain layer comprising the source and the drain;
the target drive structure is the first gate; and
the inorganic insulating layer adjacent to the target drive structure comprises the first gate insulating layer.

5. The drive back plate according to claim 4, wherein
the drive circuit further comprises a storage capacitor, wherein the storage capacitor comprises a first plate, and the second gate is reused as a second plate of the storage capacitor.

6. The drive back plate according to claim 5, wherein
the first plate is disposed between the second gate and the source-drain layer; and
the interlayer dielectric layer comprises: a first interlayer dielectric layer disposed between the second gate and the first plate, and a second interlayer dielectric layer disposed between the first plate and the source-drain layer.

7. The drive back plate according to claim 4, further comprising:
a buffer layer disposed between the base substrate and the first gate and between the base substrate and the bonding structure, wherein the inorganic insulating layer adjacent to the target drive structure further comprises the buffer layer.

8. The drive back plate according to claim 4, further comprising:
a protective layer disposed on a side of the source-drain layer away from the base substrate.

9. The drive back plate according to claim 8, further comprising:
an accommodation hole penetrating through the protective layer, the interlayer dielectric layer, the second gate insulating layer and the first gate insulating layer, wherein the bonding structure is disposed in the accommodation hole.

10. The drive back plate according to claim 1, further comprising:
an accommodation hole, wherein the bonding structure is disposed in the accommodation hole; and
a reflective structure disposed along a sidewall of the accommodation hole, wherein an orthographic projection of the reflective structure on the base substrate surrounds an orthographic projection of the bonding structure on the base substrate.

11. The drive back plate according to claim 10, wherein
the orthographic projection of the reflective structure on the base substrate is of a closed ring shape.

12. The drive back plate according to claim 10, wherein
the reflective structure covers the sidewall of the accommodation hole.

13. The drive back plate according to claim 10, comprising a first gate insulating layer, a second gate insulating layer, a first interlayer dielectric layer, a second interlayer dielectric layer and a protective layer disposed along a direction going away from the base substrate; wherein
the accommodation hole penetrates through the second interlayer dielectric layer, the first interlayer dielectric layer, the second gate insulating layer and the first gate insulating layer;
the reflective structure is extended from a side of the second interlayer dielectric layer away from the base substrate to the base substrate along the sidewall of the accommodation hole; and
the protective layer is extended into the accommodation hole along a surface, away from the sidewall of the accommodating hole, of the reflective structure and covers the reflective structure.

14. The drive back plate according to claim 10, comprising a first gate insulating layer, a second gate insulating layer, a first interlayer dielectric layer, a second interlayer dielectric layer and a protective layer disposed along a direction going away from the base substrate; wherein
the accommodation hole penetrates through the protective layer, the second interlayer dielectric layer, the first interlayer dielectric layer, the second gate insulating layer and the first gate insulating layer; and
the reflective structure is extended from a side of the protective layer away from the base substrate to the base substrate along the sidewall of the accommodation hole.

15. The drive back plate according to claim 1, wherein
the drive circuit comprises a switch unit and a storage capacitor, wherein the switch unit comprises a first gate, a first gate insulating layer, an active layer, a second gate insulating layer, a second gate, an interlayer dielectric layer and a source-drain layer which are sequentially disposed along a direction going away from the base substrate, the source-drain layer comprising a source and a drain; and the storage capacitor comprises a first plate disposed between the second gate and the source-drain layer, and the second gate is reused as a second plate of the storage capacitor; the interlayer dielectric layer comprising a first interlayer dielectric layer disposed between the second gate and the first plate, and a second interlayer dielectric layer disposed between the first plate and the source-drain layer; and the target drive structure is the first gate, and the inorganic insulating layer adjacent to the target drive structure comprises the first gate insulating layer; and
the drive back plate further comprises: a buffer layer, a protective layer and an accommodation hole, wherein
the buffer layer is disposed between the base substrate and the first gate, and between the base substrate and the bonding structure, and the inorganic insulating layer adjacent to the target drive structure further comprises the buffer layer;
the protective layer is disposed on a side of the source-drain layer away from the base substrate; and
the accommodation hole penetrates through the protective layer, the second interlayer dielectric layer, the first interlayer dielectric layer, the second gate insulating layer and the first gate insulating layer, and the bonding structure is disposed in the accommodation hole.

16. The drive back plate according to claim 1, wherein
the drive circuit comprises a switch unit and a storage capacitor, wherein the switch unit comprises a first gate, a first gate insulating layer, an active layer, a second gate insulating layer, a second gate, an interlayer dielectric layer and a source-drain layer which are sequentially disposed along a direction going away from the base substrate, the source-drain layer comprising a source and a drain; and the storage capacitor comprises a first plate disposed between the second gate and the source-drain layer, and the second gate is reused as a second plate of the storage capacitor; the interlayer dielectric layer comprising a first interlayer dielectric layer disposed between the second gate and the first plate, and a second interlayer dielectric layer disposed between the first plate and the source-drain layer; and the target drive structure is the first gate, and the inorganic insulating layer adjacent to the target drive structure comprises the first gate insulating layer; and
the drive back plate further comprises: a buffer layer, an accommodation hole, a reflective structure and a protective layer, wherein
the buffer layer is disposed between the base substrate and the first gate, and between the base substrate and the bonding structure, and the inorganic insulating layer adjacent to the target drive structure further comprises the buffer layer;
the accommodation hole penetrates through the second interlayer dielectric layer, the first interlayer dielectric layer, the second gate insulating layer and the first gate insulating layer;
the reflective structure is extended from a side of the second interlayer dielectric layer away from the base substrate to a side of the buffer layer away from the base substrate along a sidewall of the accommodation hole, an orthographic projection of the reflective structure on the base substrate is of a closed ring shape surrounding an orthographic projection of the bonding structure on the base substrate, and a material of the reflective structure is the same as a material of the source-drain layer; and
the protective layer is extended into the accommodation hole along a surface, away from the sidewall of the accommodation hole, of the reflective structure, and covers the reflective structure.

17. The drive back plate according to claim 1, wherein
the drive circuit comprises a switch unit and a storage capacitor, wherein the switch unit comprises a first gate, a first gate insulating layer, an active layer, a second gate insulating layer, a second gate, an interlayer dielectric layer and a source-drain layer which are sequentially disposed along a direction going away from the base substrate, the source-drain layer comprising a source and a drain; and the storage capacitor comprises a first plate disposed between the second gate and the source-drain layer, and the second gate is reused as a second plate of the storage capacitor; the interlayer dielectric layer comprising a first interlayer dielectric layer disposed between the second gate and the first plate, and a second interlayer dielectric layer disposed between the first plate and the source-drain layer; and the target drive structure is the first gate, and the inorganic insulating layer adjacent to the target drive structure comprises the first gate insulating layer; and
the drive back plate further comprises: a buffer layer, a protective layer, an accommodation hole and a reflective structure, wherein
the buffer layer is disposed between the base substrate and the first gate, and between the base substrate and the bonding structure, and the inorganic insulating layer adjacent to the target drive structure further comprises the buffer layer;
the protective layer is disposed on a side of the source-drain layer away from the base substrate;
the accommodation hole penetrates through the protective layer, the second interlayer dielectric layer, the first interlayer dielectric layer, the second gate insulating layer and the first gate insulating layer; and
the reflective structure is extended from a side of the protective layer away from the base substrate to a side of the buffer layer away from the base substrate along a sidewall of the accommodation hole, and an orthographic projection of the reflective structure on the base substrate is of a closed ring shape surrounding an orthographic projection of the bonding structure on the base substrate.

18. A method for manufacturing a drive back plate, comprising:
providing a base substrate; and
forming a drive circuit and a bonding structure on the base substrate, wherein the drive circuit comprises a target drive structure, a film layer disposed on at least one side of the target drive structure and adjacent to the target drive structure in the drive back plate is an inorganic insulating layer, the bonding structure and the target drive structure are disposed on a same layer, and a material of the bonding structure is the same as a material of the target drive structure.

19. A display panel, comprising:
a drive back plate and a light-emitting device, wherein
the drive back plate comprises a base substrate, and a drive circuit and a bonding structure disposed on the base substrate, wherein the drive circuit comprises a target drive structure, a film layer disposed on at least one side of the target drive structure and adjacent to the target drive structure in the drive back plate is an inorganic insulating layer, the bonding structure and the target drive structure are disposed on a same layer, and a material of the bonding structure is the same as a material of the target drive structure; and
the light-emitting device is bonded to the bonding structure.

20. A display device, comprising the display panel of claim 19.
